(19) United States
(12) Patent Application Publication
(10) Pub. No.: US 2024/0206096 A1
(43) Pub. Date: Jun. 20, 2024

(54) DISPLAY APPARATUS

(71) Applicant: LG Display Co., Ltd., Seoul (KR)

(72) Inventor: Kyounghoon KIM, Paju-si (KR)

(73) Assignee: LG Display Co., Ltd., Seoul (KR)

(21) Appl. No.: 18/525,648

(22) Filed: Nov. 30, 2023

(30) Foreign Application Priority Data
Dec. 20, 2022 (KR) 10-2022-0179497

(51) Int. Cl. H05K 5/03; H05K 7/20

(52) U.S. Cl. CPC H05K 5/03; H05K 7/20963

(57) ABSTRACT

Disclosed is a display apparatus decreased in thickness by omitting an adhesive layer that has been disposed between a cover window and a viewing angle control layer. In the display apparatus, a light shielding member is not in contact with the adhesive layer, thereby preventing bubbles from being generated in an inner end of the light shielding member and preventing the light shielding member from chafing.

### CROSS REFERENCE TO RELATED APPLICATION

The present application claims priority to Korean Patent Application No. 10-2022-0179497, filed on Dec. 20, 2022, the entire contents of which is incorporated herein for all purposes by this reference.

### BACKGROUND

### Technical Field

The disclosure relates to a display apparatus, and more particularly to a display apparatus decreased in thickness, bubbles that may be generated in a light shielding pattern of a cover window, and the moiré phenomenon.

### Discussion of the Related Art

Entering an information age, the field of display that expresses an electrical information signal visually has recently been developed rapidly, and thus various display apparatuses have been developed to have excellent performance such as thinness, light weight, and low power consumption.

As an example of the display apparatus is a liquid crystal display (LCD) apparatus, an organic light emitting display (OLED) apparatus, a quantum dot display apparatus, etc.

Such a display apparatus has recently been widely used in vehicles. In particular, an in-vehicle display apparatus is required to have special durability due to use environments where vibration occurs as a vehicle travels. Further, the display apparatus is required to have the minimum bezel for aesthetical specificity in terms of the interior design of a vehicle. In addition, the rapid spread of autonomous vehicles has led to increased multimedia viewing in vehicles, and in turn, the in-vehicle display apparatus is required to have high image quality.

### SUMMARY

Accordingly, embodiments of the present disclosure are directed to a display apparatus that substantially obviates one or more of the problems due to limitations and disadvantages of the related art.

An aspect of the disclosure is to provide a display apparatus that decreases in thickness and improves in the quality of a displayed image.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display apparatus may comprise a cover window; a light shielding pattern disposed on the cover window; a viewing angle control layer disposed on the light shielding pattern and disposed to be spaced apart from the cover window; an adhesive layer disposed on the viewing angle control layer; and a display panel disposed on the adhesive layer.

According to the disclosure, the cover window and the viewing angle control layer are spaced apart from each other to form the air gap.

According to the disclosure, light is dispersed by the air gap, thereby decreasing the moiré phenomenon.

According to the disclosure, only the thin light shielding pattern is disposed without the thick adhesive layer between the cover window and the viewing angle control layer, thereby decreasing the thickness of the display apparatus.

According to the disclosure, the inner end of the light shielding pattern is not in contact with the adhesive layer but in contact with the viewing angle control layer, thereby reducing the generation of bubbles.

According to the disclosure, the inner end of the light shielding pattern is not in contact with the adhesive layer but in contact with the viewing angle control layer, thereby preventing the light shielding pattern from chafing.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a diagram showing the front of a display apparatus according to an embodiment of the disclosure.

FIG. 2 is a cross-sectional view of a light emitting device of a display panel according to an embodiment of the disclosure.

FIG. 3 is an exploded perspective view of a display apparatus according to an embodiment of the disclosure.

FIG. 4 is a diagram showing the rear of a display apparatus according to an embodiment of the disclosure.

FIG. 5 is a perspective view showing the rear of a display apparatus according to an embodiment of the disclosure.

FIG. 6 is a cross-sectional view of a display apparatus according to an embodiment of the disclosure, taken along line B-B′ in FIG. 4.

FIG. 7 is a cross-sectional view of a display apparatus according to a comparative example, taken along line B-B′ in FIG. 4.

FIG. 8 is a view for comparison between an enlarged view of B in FIG. 6 and an enlarged view of C in FIG. 7.

FIG. 9 is a view showing that the moiré phenomenon is decreased according to an embodiment of the disclosure.

FIG. 10 is a view showing that the moiré phenomenon is decreased according to an embodiment of the disclosure

FIG. 11 is a cross-sectional view, taken along line B-B′ in FIG. 4 according to another embodiment of the disclosure.

FIG. 12 is a view showing that the moiré phenomenon is decreased according to another embodiment of the disclosure.

FIGS. 13 to 14 are cross-sectional views of a viewing angle control layer, in which FIG. 13 shows a viewing angle control function in a first mode, and FIG. 14 shows a viewing angle control function in a second mode.

### DETAILED DESCRIPTION OF THE INVENTION

Advantages and features of the disclosure and methods of accomplishing the same may be understood more readily by reference to the detailed description of embodiments that will be made hereinafter with reference to the accompanying drawings. The disclosure may, however, be embodied in many different forms and should not be construed as being limited to the exemplary embodiments set forth herein; rather, these exemplary embodiments are provided so that the disclosure will be thorough and complete and will fully convey the concept of the invention to those skilled in the art, and the present invention will only be defined by the appended claims.

The shapes, sizes, ratios, angles, numbers and the like illustrated in the drawings to describe embodiments of the disclosure are merely exemplary, and thus, the disclosure is not limited thereto. Throughout the specification, the same reference numerals refer to the same components. In addition, detailed descriptions of well-known technologies may be omitted in the disclosure to avoid obscuring the subject matter of the disclosure. When terms such as “comprises,” “has,” “includes,” or “is made up of” are used in this specification, it should be understood that unless “only” is specifically used, additional elements or steps can be included. Unless otherwise explicitly stated, when a component is expressed in the singular form, it is intended to encompass the plural form as well.

In interpreting the components, it is construed to include a margin of error even in the absence of explicit description.

When describing the positional relationship, for example, when the relationship between two parts is described as “on”, “on top of”, “underneath”, “beside”, etc., unless “directly” or “immediately” is used, one or more other parts may be located between the two parts.

When a device or layer is referred to as being “on” another device or layer, it includes cases where one device or layer is directly located on the other device or layer or still other device or layer is interposed between the two devices or layers.

Although the terms “first”, “second”, and the like are used to describe various components, these components are not limited by these terms. These terms are merely used for distinguishing one component from the other components. Therefore, the first component mentioned hereinafter may be the second component in the technical sense of the disclosure.

Throughout the specification, the same reference numerals refer to the same components.

The sizes and thicknesses of each component shown in the drawings are presented for the convenience of description and are not intended to limit the disclosure.

The features of various embodiments of the disclosure can be partially or entirely combined or assembled in various technical manners of interlocking and interoperation obvious to those skilled in the art, and each embodiment can be implemented independently or in combination with related embodiments.

Hereinafter, detailed descriptions are made of the embodiments of the disclosure with reference to the accompanying drawings.

In the disclosure, the term “display apparatus” is used in a narrow sense to refer to display apparatuses, such as a liquid crystal module (LCM), an organic light-emitting diode (OLED) module, and a quantum dot module, each including a display panel and a panel driving unit to operate the display panel. In addition, the term may also be used to refer to set electronic devices, set devices, or apparatuses that include LCMs, OLED modules, QD modules, and the like, such as equipment display apparatuses including complete or final products such as laptop computers, televisions, computer monitors, automotive displays or equipment displays provided in other forms for vehicles, as well as mobile electronic devices such as smartphones or electronic pads.

Accordingly, in the disclosure, the display apparatus may include not only the display apparatuses in the narrow sense themselves, such as LCMs, OLED modules, QD modules, but also set devices as application products or final consumer devices including LCMs, OLED modules, QD modules, and the like.

Additionally, in some cases, an LCM, an OLED module, or a QD module, composed of a display panel and a panel driving unit may be referred to as “display apparatus” in a narrow sense, while an electronic device as a complete product including an LCM, an OLED module, or a QD module may be referred to as “set device”. For example, the narrow-sense display apparatus may include a display panel of liquid crystal (LCD), organic light-emitting diode (OLED), or quantum dot (QD) and a source printed circuit board (PCB) as a control unit for driving the display panel, while a set device may further include a set PCB, serving as a set control unit that is electrically connected to the source PCB and controls the entire set device.

The display panel used in the embodiments may include all types of display panels such as liquid crystal display panels, organic light-emitting diode (OLED) display panels, quantum dot (QD) display panels, and electroluminescent display panels, and is not limited to a specific display panel capable of bending a bezel with a flexible substrate for OLED display panel and a backplate support structure thereunder. In addition, the display panel used in the embodiments of the disclosure is not limited to the shape or size of the display panel.

For example, when the display panel is an organic light-emitting diode (OLED) display panel, it may include a plurality of gate lines and data lines and pixels formed at the intersection of the gate lines and data lines. In addition, it may be configured to include an array including thin-film transistors as components for selectively applying voltage to each pixel, an organic light-emitting diode (OLED) layer on the array, an encapsulation substrate or encapsulation layer arranged on the array to cover the organic light-emitting diode layer, etc. The encapsulation layer may protect the thin film transistors and the organic light-emitting device layer from the external impacts and prevent moisture or oxygen from penetrating into the organic light-emitting device layer. In addition, the layers formed on the array may for example include an inorganic light-emitting layer, such as a nano-sized material layer or quantum dots.

In the disclosure, a display panel illustrates an exemplary organic light emitting diode (OLED) display panel that may be integrated within display apparatuses.

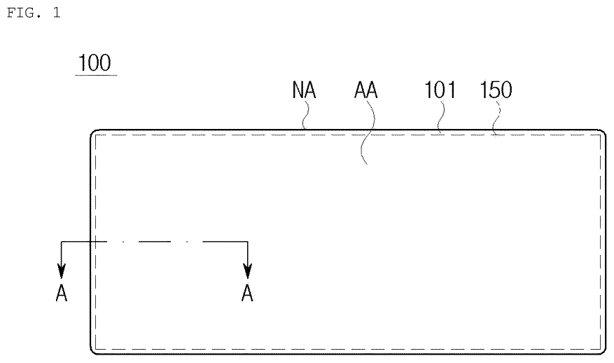

FIG. 1 is a diagram illustrating a display apparatus 100 according to an embodiment of the disclosure.

Referring to FIG. 1, the display apparatus 100 may be applied to a TV, a monitor, a PC, the center fascia of a vehicle, etc. Although FIG. 1 shows an approximately rectangular display panel 150, the shape of the display apparatus 100 is not necessarily limited thereto and can be produced in various shapes such as squares, polygons, or curves.

Referring to FIG. 1, the display apparatus 100 includes a cover window 101 and a display panel 150. The cover window 101 may be formed of a glass or plastic material to protect the display panel 150 from external shock.

The display panel 150 is formed beneath the cover window 101, and coupled to the cover window 101 through an adhesive member. The display panel 150 may include a polarization plate, a panel layer, and a touch panel. In particular, when the display panel 150 is an in-vehicle display panel, a viewing angle control film for controlling a viewing angle by controlling light emitted toward a driver. Such a viewing angle control film is a particular form the display apparatus 100 mounted to a vehicle. In particular, the display apparatus 100 that has recently been mounted to a vehicle is disposed in the front of a driver seat to display a speedometer or the like, disposed at the center to display a navigation or the like, and disposed in the front of a passenger seat to display a multimedia to an occupant who is seated in the passenger seat. Further, recently, an integrated display apparatus 100 is formed from the front of the driver seat to the front of the passenger seat via the center. Therefore, the viewing angle control film is essential to avoid transfer of an image displayed for the passenger seat to a driver.

The display apparatus 100 includes a display area AA where a user can view a video or image in the front thereof, and a non-display area NA where an image is not displayed. Such a non-display area NA may also be referred to as a bezel area.

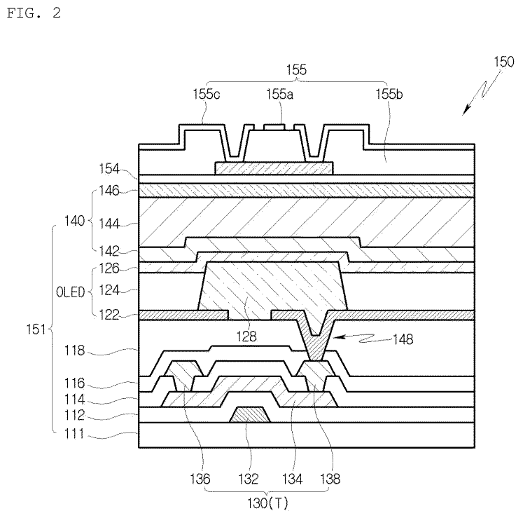

FIG. 2 is a cross-sectional view of a light emitting device of a display panel according to an embodiment of the disclosure.

Referring to FIG. 2, a substrate 111 is disposed at the bottom of the display panel 150. The substrate 111 may support various components of the display panel 150. The substrate 111 may be formed of a transparent dielectric material such as glass, plastic, and the like. In the case of being formed of plastic, the substrate 111 may be a plastic film or a plastic substrate. For example, the substrate 111 may take the form of a film including one of the polyimide-based polymers, polyesters-based polymers, silicone-based polymers, acrylic-based polymers, polyolefin-based polymers, and their copolymers. Among these materials, polyimide is mainly used as a plastic substrate because it is suitable for high-temperature processes and is a material that can be coated.

Although it is not shown, a buffer layer may be positioned on the substrate 111. The buffer layer is a functional layer that protects the thin-film transistor (TFT) from impurities such as alkali ions that may leak from the bottom of the substrate 111. The buffer layer may be formed of silicon oxide (Siox), silicon nitride (SiNx), or multiple layers thereof.

Thin film transistor 130 may be disposed on the buffer layer. The thin film transistor 130 may be formed by sequentially arranging a gate electrode 132, a gate insulating layer 112, a semiconductor layer 134, an interlayer insulating film 114, and source and drain electrodes 136 and 138 on the buffer layer. There may be one or more thin film transistors 130 arranged for a plurality of sub-pixels provided in the active area.

Although illustrated as the bottom-gate type in FIG. 2, the thin film transistor 130 is not limited thereto and may also be provided as the top-gate type, in which the order of the semiconductor layer 134 and the gate electrode 132 are reversed.

The semiconductor layer 134 may be arranged at a specific portion on the substrate 111 or on the buffer layer. The semiconductor layer 134 may be made of polycrystalline silicon (p-Si), and in this case, a region of the semiconductor layer 134 may be doped with impurities to form the electrode layer. The semiconductor layer 134 may also be made of amorphous silicon (a-Si) and various organic semiconductor materials such as pentacene. Furthermore, the semiconductor layer 134 may also be made of an oxide material. The gate insulating layer 112 may be formed of inorganic dielectric materials such as silicon oxide (Siox) or silicon nitride (SiNx) and organic dielectric materials. The gate electrode 132 may be formed of various conductive materials, such as magnesium (Mg), aluminum (Al), nickel (Ni), chromium (Cr), molybdenum (Mo), tungsten (W), gold (Au), or alloys thereof.

The first interlayer insulating film 114 may be formed of inorganic dielectric materials such as silicon oxide (Siox) or silicon nitride (SiNx) and, as well, organic dielectric materials. The first interlayer insulating film 114 may be selectively removed to form contact holes exposing the source and drain regions.

The source and drain electrodes 136 and 138 are formed as a single layer or multilayer of electrode material on the first interlayer insulating film 114.

An inorganic protective film 116 and a planarization layer 118 may be positioned on the thin film transistor 130 to cover the source and drain electrodes 136 and 138. The inorganic protective film 116 and the planarization layer 118 protect the thin film transistor 130 and flatten its upper surface.

The inorganic protective film 116 may be formed of inorganic dielectric films such as silicon nitride (SiNx) and silicon oxide (SiOx), while the planarization layer 118 may be made of organic dielectric films such as Benzocyclobutene (BCB) or acrylic (Acryl). The inorganic protective film 116 and the planarization layer 118 may each be formed as a single layer, dual-layer, or multilayer structure, and in some cases, one of the two layers may be omitted.

A light-emitting component OLED connected to the thin film transistor (TFT) 130 may be formed by sequentially arranging a first electrode 122, an organic light-emitting layer 124, and a second electrode 126. That is, the light-emitting component OLED may be composed of the first electrode 122 connected to the drain electrode 138 through a connection hole 148 formed in the planarization layer 118 and the inorganic protective film 116, the organic light emitting layer 124 position on the first electrode 122, and the second electrode 126 positioned on the organic light-emitting layer 124.

When the display panel 150 is of a top emission type where the emission occurs upward through the second electrode 126, the first electrode 122 may include an opaque conductive material with high reflectivity. In this case, examples of the reflective conductive material may include silver (Ag), aluminum (Al), gold (Au), molybdenum (Mo), tungsten (W), chromium (Cr), or alloys thereof.

A bank 128 is formed in the area excluding the light-emitting area, opening up the light-emitting area. Accordingly, the bank 128 has a bank hole exposing the first electrode 122 corresponding to the light-emitting area. The bank 128 may be made of inorganic dielectric materials such as silicon nitride (SiNx), silicon oxide (Siox), or organic dielectric materials such as BCB, acrylic-based resins, or imide-based resins.

The organic light-emitting layer 124 is positioned on the first electrode 122 exposed by the bank 128. The organic light-emitting layer 124 may include a hole injection layer, a hole transport layer, an emissive layer, an electron transport layer, and an electron injection layer. In addition, the organic light-emitting layer 124 may be composed of a single emissive layer structure that emits a single light within a single stack, or a multi-stack structure including multiple stacks, each of which includes a single emissive layer of the same color. In such cases, adjacent sub-pixels may be arranged to emit different colors of light to display various colors. For example, sub-pixels with emissive layers of red, green, and blue may be arranged in a row or spaced apart from each other and, in a triangle shape or pentile structure with some sub-pixels of predetermined colors aligned in parallel and others aligned diagonally to each other.

In some cases, sub-pixels of white color may also be added to the arrangement. In addition, the organic light-emitting layer 124 may be configured by stacking a plurality of stacks including emissive layers emitting different colors of light to express white. In the case of expressing white with a stacked structure, separate color filters may be additionally added to each sub-pixel.

The second electrode 126 is position on the organic light-emitting layer 124. When the display panel 150 adopts a top emission structure, the second electrode 126 may be formed of a transparent conductive material such as indium tin oxide (ITO) or indium zinc oxide (IZO) or a semi-transparent metal or metal alloy such as Mg and Ag to emit light generated in the organic light-emitting layer 124 upward through the second electrode 126.

The second electrode 126 may be arranged to reach a capping layer. The capping layer may protect the OLED and assist in the extraction of light emitted through the second electrode 126 by using a material with a high refractive index.

An encapsulation layer 140 may be disposed on the light-emitting component OLED. The encapsulation layer 140 prevents the infiltration of oxygen and moisture from the outside to prevent oxidation of the emissive and electrode materials. Exposure of OLED to moisture or oxygen may cause pixel shrinkage or the formation of dark spots, reducing the emitting area. The encapsulation layer 140 is formed by alternately stacking inorganic layers 142 and 146 made of glass, metal, aluminum oxide (Alox), or silicon (Si) materials and an organic layer 144 that serves as a buffer relieving the stress between layers due to the bending of the display panel (100 in FIG. 1) and enhances the flattening performance. The organic layer 144 may be made of organic dielectric materials such as acrylic resin, epoxy resin, polyimide, polyethylene, or silicon oxycarbide (SiOC). Here, the first and second inorganic layers 142 and 146 serve to block the penetration of moisture or oxygen, while the organic layer 144 flattens the surface of the first inorganic layer 142. The encapsulation layer 140 is composed of several thin film layers to increase the length and complexity of the path that moisture and oxygen must travel compared to a single layer, with the purpose of making it difficult for moisture and oxygen to penetrate to the light-emitting component OLED.

A protective layer may be formed further between the light-emitting component OLED and the encapsulation layer 140 to protect the encapsulation layer 140 from being peeled off or affecting the uniformity during the manufacturing process of the encapsulation layer 140.

Referring to FIG. 2, a polarization layer 154 may be disposed on the encapsulation layer 140. The polarization layer 154 may minimize the impact of light entering the display panel 150 from external light sources on the semiconductor layer 134 or the organic light-emitting layer 124.

Referring to FIG. 2, a touch sensor layer 155 may be arranged on the polarization layer 154. The touch sensor layer 155 may be structured with the first touch electrode 155a and the second touch electrode 155c intersecting each other, allowing one electrode to receive an applied voltage signal and the other to sense the voltage signal. The first touch electrode 155a and the second touch electrode 155c may be patterned into polygonal or circular shapes on a touch insulation film 155b to be arranged at a distance from each other.

A front cover member 101 may be disposed on the touch sensor layer 155. An adhesive layer is further disposed between the touch sensor layer 155 and the front cover member 101 to bond them together.

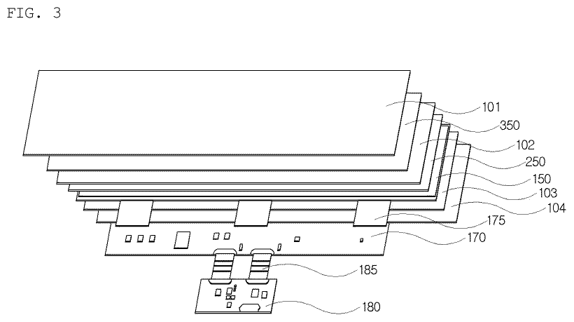

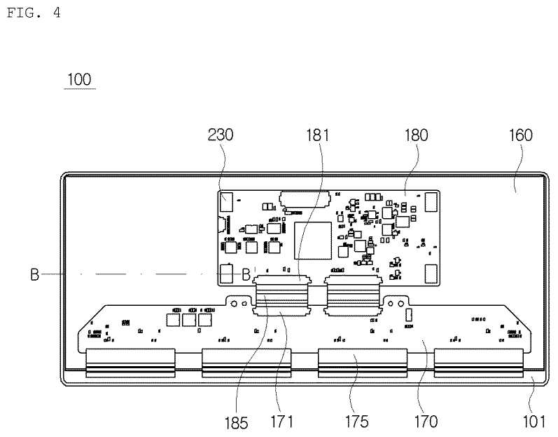

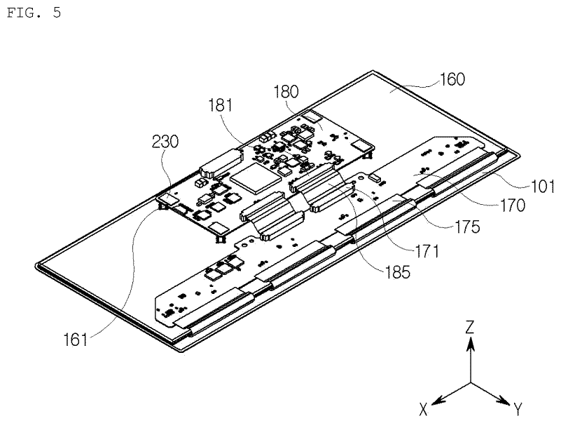

FIG. 3 is an exploded perspective view of a display apparatus according to an embodiment of the disclosure. FIG. 4 is a diagram showing the rear of a display apparatus according to an embodiment of the disclosure. FIG. 5 is a perspective view showing the rear of a display apparatus according to an embodiment of the disclosure.

FIG. 3 illustrates that the cover window 101 is positioned at the top, and FIGS. 4 and 5 illustrate that the cover window 101 is disposed at the bottom. In this disclosure, a lower or bottom refers to a direction where the cover window 101 is disposed, and an upper or top refers to a direction opposite the direction.

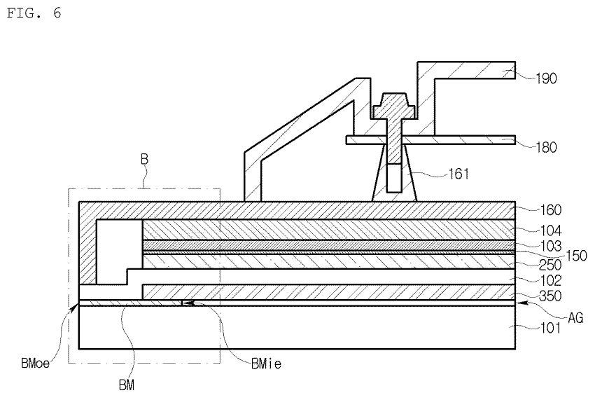

FIG. 3 depicts that a guide holder 160 is removed. FIGS. 4 and 5 depict that the guide holder 160 covers the cover window 101. As shown in the cross-sectional views of FIGS. 3 and 6, a viewing angle control layer 350, an adhesive member 102, a polarization film 250, the display panel 150, a back plate 103, a heat dissipation plate 104 and the like component may further be disposed between the cover window 101 and the guide holder 160. However, these components have a thickness of a few millimeters, and are thus omitted the rear view of FIG. 4 and the rear perspective view of FIG. 5.

Further, as shown in the cross-sectional view of FIG. 6, a back cover 190 may further be disposed on the guide holder 160. To describe the rear of the display apparatus 100 in detail, the back cover 190 is removed in FIGS. 4 and 5. In describing FIGS. 3 to 5, the reference will be made together with the cross-sectional view of FIG. 6.

The display apparatus 100 according to an embodiment of the disclosure may include the cover window 101, the viewing angle control layer 350, the adhesive member 102, the polarization film 250, the display panel 150, the back plate 103, the heat dissipation plate 104, the guide holder 160, a source printed circuit board 170, and a control printed circuit board 180.

The cover window 101 may be disposed on the front surface of the display panel 150 and made of, but not limited to, a glass material having high strength. Further, the cover window 101 may include the display area AA (see FIG. 1) and the non-display area NA (see FIG. 1). The display area AA may be an area corresponding to the display panel 150, and the non-display area NA may correspond to the bezel area. The bezel area may be formed with a light shielding pattern. Therefore, the display apparatus 100 may include the light shielding pattern formed at four edges of upper, lower, left and right sides when viewed from the front.

The light shielding pattern may be formed of an ink material as a black colored material. For example, the light shielding pattern may be formed by ink printing. The light shielding pattern may include a single layer formed by a 1-color printing method, or a double layer formed by a 2-color printing method. Further, the light shielding pattern may include three or more layers formed by a 3-color printing method.

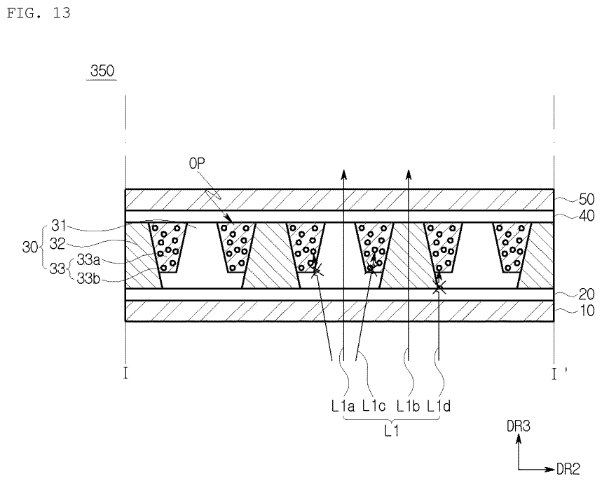

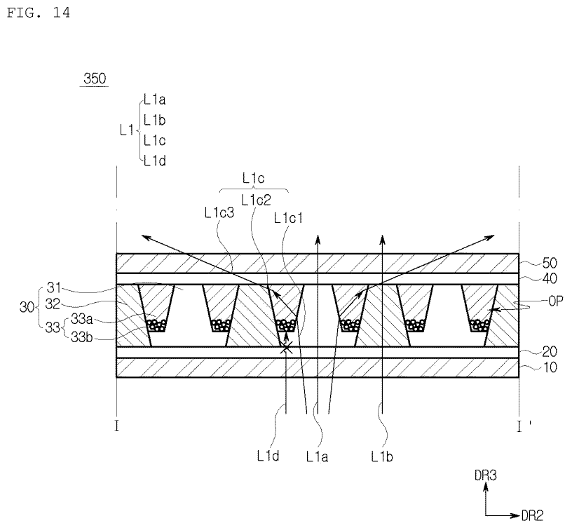

The viewing angle control layer 350 serves to control a direction of light emitted from the display panel 150 and may be disposed on the side of the cover window 101, i.e., the front end of the display panel 150. In particular, the display apparatus 100 mounted to a vehicle may need to be controlled to selectively emit light to a driver or not to emit light. In this way, the viewing angle control layer 350 may selectively control the path of light emitted from the display panel 150. The viewing angle control layer 350 will be described later in detail with reference to FIGS. 13 and 14.

The adhesive member 102 serves to bond the cover window 101 and the viewing angle control layer 350 to each other. In addition, the adhesive member 102 serves to bond the polarization film 250 to the viewing angle control layer 350. The adhesive member 102 may include a transparent material, for example, an optical clear adhesive (OCA) or a pressure sensitive adhesive (PSA).

The polarization film 250 is disposed on the adhesive member 102. The polarization film 250 serves to prevent external light from being reflected from the display panel 150.

The display panel 150 is disposed on the polarization film 250. The display panel 150 emits light for displaying a video or image, and internally includes a plurality of pixels and transistors for driving the pixels. The detailed structure of the display panel 150 is the same as exemplarily described with reference to FIG. 2.

The back plate 103 is disposed on the display panel 150. The back plate 103 may serve as a rigid structure to reinforce the rigidity of the display panel 150. The back plate 103 may be formed of a plastic thin film.

The heat dissipation plate 104 is disposed on the back plate 103. The heat dissipation plate 104 may serve to dissipate heat generated in the display panel 150 or the printed circuit boards 170 and 180. The heat dissipation plate 101 may include aluminum, magnesium or the like metal material, or a plastic material excellent in thermal conductivity.

Referring to FIGS. 4 and 5, the guide holder 160 is disposed on the heat dissipation plate 104. The guide holder 160 may serve to protect the components positioned below, and support the control printed circuit board 180. To support the control printed circuit board 180, the guide holder 160 may include a substrate supporting member 161. The guide holder 160 may be formed of a metal or plastic material.

The back cover 190 (see FIG. 6) may be disposed on the guide holder 160. The back cover 190 may serve to protect the printed circuit boards 170 and 180 positioned below. The back cover 190 may be screw-coupled to the guide holder 160. The back cover 190 may be formed of a metal or plastic material.

The guide holder 160 may be disposed on the top surface of the display panel 150. According to an embodiment of the disclosure, the guide holder 160 may be made of, but not limited to, an aluminum material excellent in thermal conductivity. For example, the guide holder 160 may include a synthetic metal material including magnesium. Further, the guide holder 160 may be made of a plastic material.

The guide holder 160 may be bonded to the rear of the display panel 150. Therefore, the guide holder 160 may function as a heat dissipation plate to dissipate and remove heat from the display panel 150.

The guide holder 160 may be fabricated to perform a function of holding the source printed circuit board 170 and the control printed circuit board 180 as well. For example, the guide holder 160 may include a substrate supporting block 161, and the control printed circuit board 180 may be disposed on the substrate supporting block 161. There may be a plurality of such substrate supporting blocks 161.

The source printed circuit board 170 may be disposed on the rear of the guide holder 160, and the source printed circuit board 170 may be connected to the display panel 150 by a flexible circuit board 175. The flexible circuit board 175 may be provided as a chip on film (COF) and internally include a source driver integrated circuit (IC).

The control printed circuit board 180 may be disposed in the substrate supporting block 161 formed in the guide holder 160, and connected to the source printed circuit board 170 by a flat cable 185. Specifically, a first connector 171 disposed in the source printed circuit board 170 and a second connector 181 disposed in the control printed circuit board 180 are connected by a flat cable 185, so that the control printed circuit board 180 can control the source printed circuit board 170.

The back cover 190 (see FIG. 6) may be disposed on the guide holder 160, and coupled to the guide holder 160 by, for example, a screw, while surrounding and protecting the source printed circuit board 170 and the control printed circuit board 180. The back cover 190 may be made of, but not limited to, a synthetic metal material including magnesium or a polycarbonate (PC) material. For example, the back cover 190 may be made of a plastic material.

FIG. 6 is a cross-sectional view of a display apparatus according to an embodiment of the disclosure, taken along line B-B′ in FIG. 4. With reference to FIG. 6, the display apparatus 100 according to an embodiment of the disclosure will be described.

The cover window 101 is disposed on the bottom of the display apparatus 100. The light shielding pattern BM is disposed on an outer portion of the cover window 101. The light shielding pattern BM is not disposed throughout the entire surface of the cover window 101, but formed having a certain width along the outer portion of the cover window 101 to define a bezel. One of both ends of the light shielding pattern BM may be defined as an outer end BMoe disposed at the outer side of the display apparatus, and the other end may be defined as an inner end BMie disposed at the inner side of the display apparatus.

The viewing angle control layer 350 is disposed on the light shielding pattern BM. The viewing angle control layer 350 is partially in direct contact with the top of the light shielding pattern BM. Specifically, the viewing angle control layer 350 covers the inner end BMie of the light shielding pattern BM. Therefore, an air gap AG is formed in an area where the viewing angle control layer 350 is not in direct contact with the light shielding pattern BM. The air gap AG may be defined as a space between the cover window 101 and the viewing angle control layer 350.

The adhesive layer 102 is disposed to cover the top of the light shielding pattern BM and the viewing angle control layer 350. The adhesive layer 102 is partially in direct contact with the top of the light shielding pattern BM, and is in direct contact with the lateral side and top of the viewing angle control layer 350. Therefore, the adhesive layer 102 serves to bond the cover window 101 and the viewing angle control layer 350 to each other. Besides, the adhesive layer 102 serves to bond the viewing angle control layer 350 and the polarization film 250 to each other. Further, the adhesive layer 102 is not in contact with the inner end BMie of the light shielding pattern BM.

The polarization film 250, the display panel 150, the back plate 103 and the heat dissipation plate 104 are stacked on the adhesive layer 102 in order. However, without limitation, some components may be omitted, another component may be added, and the stacking order of these components may be changed.

The guide holder 160 is disposed on the heat dissipation plate 104. The guide holder 160 may be formed with the substrate supporting block 161, and the control printed circuit board 180 is disposed on the substrate supporting block 161. The back cover 190 is disposed on the control printed circuit board 180, and the back cover 190, the control printed circuit board 180 and the substrate supporting block 161 may be coupled to each other by a screw.

In other words, according to an embodiment of the disclosure, the cover window 101 and the viewing angle control layer 350 are spaced apart from each other with the light shielding pattern BM therebetween, and thus the air gap AG may be formed between the cover window 101 and the viewing angle control layer 350. The height of the air gap AG may be a spacing distance between the viewing angle control layer 350 and the cover window 101. The spacing distance may correspond to the height of the light shielding pattern BM. For example, the light shielding pattern BM may have a height of 8 μm, and thus the air gap AG may also have a height of 8 μm.

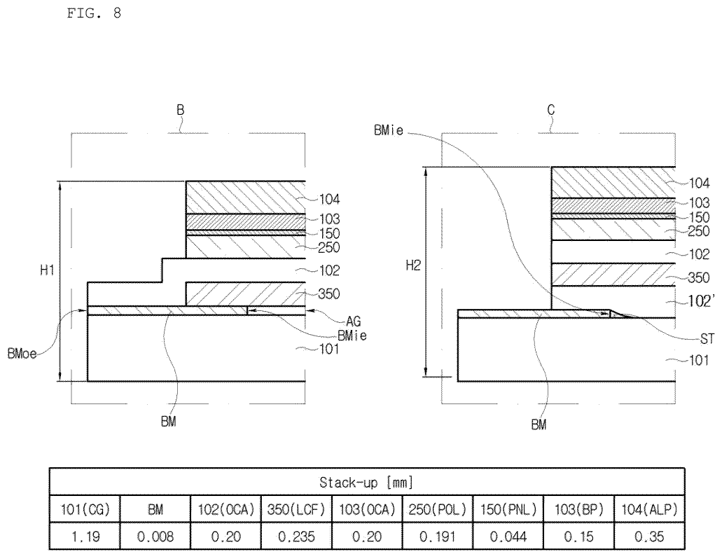

Further, the inner end BMie of the light shielding pattern BM is not in contact with the adhesive layer 102. On the other hand, if the inner end BMie of the light shielding pattern BM is in contact with the adhesive layer 102, problems such as generation of bubbles or chafing of the light shielding pattern may arise. For example, the adhesive layer 102 of the OCA material shrinks when cured, and at this time bubbles are generated in a step-like portion between the inner end BMie and the adhesive layer 102. Besides, the light shielding pattern chafes while the inner end BMie shrinks. According to an embodiment of the disclosure, the inner end BMie of the light shielding pattern BM is not in contact with the adhesive layer 102, and thus the foregoing problem does not arise. In this regard, details will be described later with reference to FIG. 8.

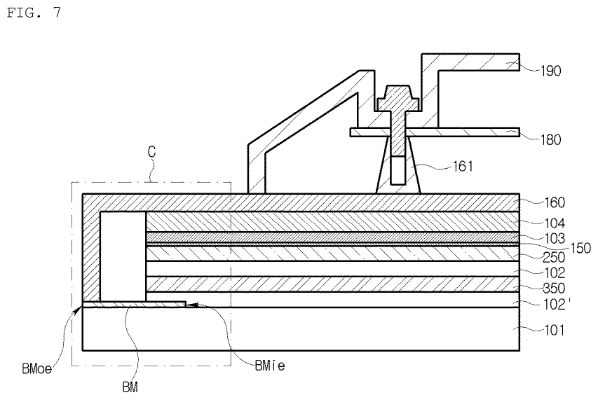

FIG. 7 is a cross-sectional view of a display apparatus according to a comparative example, taken along line B-B′ in FIG. 4.

The cover window 101 is disposed on the bottom of the display apparatus 100. The light shielding pattern BM is formed on an outer portion of the cover window 101. The light shielding pattern BM is not disposed throughout the entire surface of the cover window 101, but formed having a certain width along the outer portion of the cover window 101 to define a bezel. One of both ends of the light shielding pattern BM may be defined as an outer end BMoe disposed at the outer side of the display apparatus, and the other end may be defined as an inner end BMie disposed at the inner side of the display apparatus.

A second adhesive layer 102′ is disposed on the light shielding pattern BM. The second adhesive layer 102′ serves to bond the cover window 101 and the viewing angle control layer 350 to each other. The second adhesive layer 102′ is formed to cover the inner end BMie of the light shielding pattern BM. Further, the second adhesive layer 102′ is formed throughout the entire surface of the cover window 101. Therefore, the air gap AG shown in FIG. 6 is not formed between the cover window 101 and the viewing angle control layer 350.

The viewing angle control layer 350 is formed on the second adhesive layer 102′. The viewing angle control layer 350 is coupled to the cover window 101 through the second adhesive layer 102′.

The adhesive layer 102 is formed on the viewing angle control layer 350. The adhesive layer 102 serves to bond the viewing angle control layer 350 and the polarization film 250 to each other.

The polarization film 250, the display panel 150, the back plate 103 and the heat dissipation plate 104 are stacked on the adhesive layer 102 in order. However, without limitation, some components may be omitted, another component may be added, and the stacking order of these components may be changed.

The guide holder 160 is disposed on the heat dissipation plate 104. The guide holder 160 may be formed with the substrate supporting block 161, and the control printed circuit board 180 is disposed on the substrate supporting block 161. The back cover 190 is disposed on the control printed circuit board 180, and the back cover 190, the control printed circuit board 180 and the substrate supporting block 161 may be coupled to each other by a screw.

FIG. 8 is a view for comparison between an enlarged view of B in FIG. 6 and an enlarged view of C in FIG. 7.

Referring to the enlarged view B according to an embodiment of the disclosure, the cover window 101, the light shielding pattern BM, the viewing angle control layer 350, the adhesive layer 102, the polarization film 250, the display panel 150, the back plate 103 and the heat dissipation plate 104 are stacked in a direction from the bottom to the top. Therefore, such a stacked structure has a total height H1 of about 2.368 mm.

Referring to the enlarged view C according to a comparative example, the cover window 101, the light shielding pattern BM, the second adhesive layer 102′, the viewing angle control layer 350, the adhesive layer 102, the polarization film 250, the display panel 150, the back plate 103 and the heat dissipation plate 104 are stacked in a direction from the bottom to the top. Here, when the second adhesive layer 102′ is the OCA, the height of the light shielding pattern BM does not affect a total height H2. Therefore, the total height H2 is about 2.56 mm.

The height H1 according to an embodiment of the disclosure may is reduced by 0.192 mm compared to the height H2 according to the comparative example. The reduced height is about 7.5% of the total height. Therefore, according to an embodiment of the disclosure, the display apparatus is decreased in thickness, and thus the display apparatus can become lighter and thinner.

Meanwhile, referring to the enlarged view B according to an embodiment of the disclosure, the inner end BMie of the light shielding pattern BM overlaps with the viewing angle control layer 350 but does not overlap with the adhesive layer 102. On the other hand, referring to the enlarged view C according to the comparative example, the inner end BMie of the light shielding pattern BM overlaps with the second adhesive layer 102′.

Because the second adhesive layer 102′ is made of the OCA or the like material, bubbles are generated in a portion where the bottom of the second adhesive layer 102′ is separated from the cover window 101 due to the height of the inner end BMie of the light shielding pattern BM after the second adhesive layer 102′ is cured. This causes a problem that the bubbles ST are viewed by a user in the front of the display apparatus. Further, the OCA is decreased in volume when cured, and thus the light shielding pattern BM chafes in the portion of the bubbles ST, thereby causing a problem that such chafing is viewed by a user with his/her naked eyes in the front.

According to an embodiment of the disclosure, the inner end BMie of the light shielding pattern BM is not in contact with the adhesive layer 102. Instead, the inner end BMie of the light shielding pattern BM overlaps the viewing angle control layer 350 formed of rigid glass or plastic. Therefore, the bubbles ST or chafing phenomenon of the comparative example are prevented.

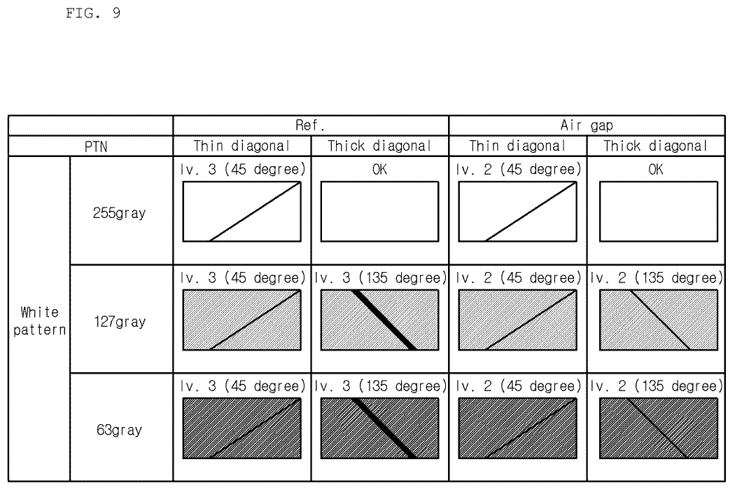

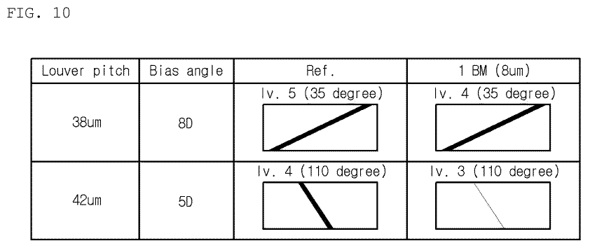

Meanwhile, referring to the enlarged view B according to an embodiment of the disclosure, the air gap AG is formed. On the other hand, referring to the enlarged view C according to the comparative example, the air gap AG is not formed. The air gap AG formed according to an embodiment of the disclosure is formed throughout the entire surface of the display apparatus. The air gap AG may decrease the moiré phenomenon observed by a user with his/her naked eyes. According to an embodiment of the disclosure, the effects of decreasing the moiré phenomenon will be described with reference to FIGS. 9 and 10.

FIG. 9 is a view showing that the moiré phenomenon is decreased according to an embodiment of the disclosure.

The moiré phenomenon refers to a phenomenon where lines are observed by a user with his/her naked eyes due to superimposed patterns of two layers spaced apart from each other. The moiré phenomenon deteriorates the quality of an image on the display apparatus.

The display apparatus according to an embodiment of the disclosure includes the viewing angle control layer 350 and the display panel 150. Referring to FIGS. 13 to 14 showing the cross-sectional structure of the viewing angle control layer 350, light converters 30 are disposed at regular pitches. Here, the light converter 30 is referred to as a louver. Referring to FIG. 2 showing the cross-sectional structure of the display panel 150, subpixels are disposed at regular pitches. Therefore, the moiré phenomenon easily occurs as the louver pattern of the viewing angle control layer 350 and the pixel pattern of the display panel 150 are overlapped.

According to an embodiment of the disclosure, the air gap AG is formed between the cover window 101 and the viewing angle control layer 350. The air gap AG additionally provides an air layer having a different refractive index, thereby reducing the level of moiré caused by diffuse reflection.

Referring to FIG. 9, in the case of the comparative example Ref., a 3-level thin diagonal line of 45 degrees was observed in a 255-gray pattern. In the case of an embodiment Air gap of the disclosure, a 2-level thin diagonal line was observed under the same condition, thereby reducing the level of moiré.

Further, in the case of the comparative example, a 3-level thin diagonal line of 45 degrees was observed in a 127-gray pattern, but in the case of an embodiment Air gap of the disclosure, a 2-level thin diagonal line was observed under the same condition. In addition, a 3-level thick diagonal line of 135 degrees was observed, but a 2-level thick diagonal line according to an embodiment of the disclosure was observed under the same condition.

Further, in the case of the comparative example, a 3-level thin diagonal line of 45 degrees was observed in a 63-gray pattern, but in the case of an embodiment of the disclosure, a 2-level thin diagonal line was observed under the same condition. In addition, a 3-level thick diagonal line of 135 degrees was observed, but a 2-level thick diagonal line according to an embodiment of the disclosure was observed under the same condition.

Therefore, the effects of reducing the moiré phenomenon according to an embodiment of the disclosure was confirmed.

FIG. 10 is a view showing that the moiré phenomenon is decreased according to an embodiment of the disclosure.

In the case of a viewing angle control layer manufactured with a louver pitch of 38 μm, when a bias angle is set to 8 degrees (8D), 5-level moiré was observed in a direction of 35 degrees in the comparative example, but 4-level moiré was observed in an embodiment of the disclosure.

In the case of a viewing angle control layer manufactured with a louver pitch of 42 μm, when a bias angle is set to 5 degrees (5D), 4-level moiré was observed in a direction of 110 degrees in the comparative example, but 3-level moiré was observed in an embodiment of the disclosure.

Therefore, the effects of reducing the moiré phenomenon according to an embodiment of the disclosure was confirmed.

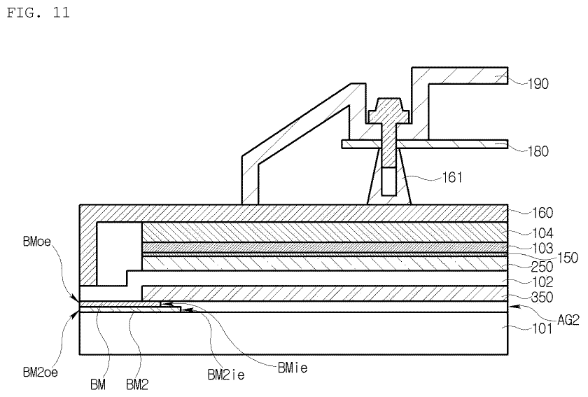

FIG. 11 is a cross-sectional view, taken along line B-B′ in FIG. 4 according to another embodiment of the disclosure. This embodiment is different from the embodiment shown in FIG. 6 in that a second light shielding pattern BM2 is additionally formed beneath the light shielding pattern BM. Therefore, an air gap AG2 may be formed more largely.

The cover window 101 is disposed on the bottom of the display apparatus 100. The light shielding pattern BM and a second light shielding pattern BM2 are disposed on an outer portion of the cover window 101. The light shielding pattern BM and the second light shielding pattern BM2 are not disposed throughout the entire surface of the cover window 101, but formed having a certain width along the outer portion of the cover window 101 to define a bezel. One of both ends of the light shielding pattern BM may be defined as an outer end BMoe disposed at the outer side of the display apparatus, and the other end may be defined as an inner end BMie disposed at the inner side of the display apparatus. Further, one of both ends of the second light shielding pattern BM2 may be defined as an outer end BM2oe, and the other end may be defined as an inner end BM2ie.

The viewing angle control layer 350 is disposed on the light shielding pattern BM and the second light shielding pattern BM2. The viewing angle control layer 350 is partially in direct contact with the top of the light shielding pattern BM. Specifically, the viewing angle control layer 350 covers the inner end BMie of the light shielding pattern BM. Therefore, an air gap AG2 is formed in an area where the viewing angle control layer 350 is not in direct contact with the light shielding pattern BM and the second light shielding pattern BM2. The air gap AG2 may be defined as a space between the cover window 101 and the viewing angle control layer 350. The air gap AG2 is larger than the air gap AG described with reference to FIG. 6 because the light shielding pattern is formed as a double layer.

The adhesive layer 102 is disposed to cover the top of the light shielding pattern BM and the viewing angle control layer 350. The adhesive layer 102 is partially in direct contact with the top of the light shielding pattern BM, and is in direct contact with the lateral side and top of the viewing angle control layer 350. Therefore, the adhesive layer 102 serves to bond the cover window 101 and the viewing angle control layer 350 to each other. Besides, the adhesive layer 102 serves to bond the viewing angle control layer 350 and the polarization film 250 to each other. Further, the adhesive layer 102 is not in contact with the inner end BMie of the light shielding pattern BM and the inner end BM2ie of the second light shielding pattern BM2.

The polarization film 250, the display panel 150, the back plate 103 and the heat dissipation plate 104 are stacked on the adhesive layer 102 in order. However, without limitation, some components may be omitted, another component may be added, and the stacking order of these components may be changed.

The guide holder 160 is disposed on the heat dissipation plate 104. The guide holder 160 may be formed with the substrate supporting block 161, and the control printed circuit board 180 is disposed on the substrate supporting block 161. The back cover 190 is disposed on the control printed circuit board 180, and the back cover 190, the control printed circuit board 180 and the substrate supporting block 161 may be coupled to each other by a screw.

In other words, according to an embodiment of the disclosure, the cover window 101 and the viewing angle control layer 350 are disposed with the light shielding pattern BM and the second light shielding pattern BM2 therebetween, and thus the air gap AG2 is formed between the cover window 101 and the viewing angle control layer 350. The height of the air gap AG2 may be a spacing distance between the viewing angle control layer 350 and the cover window 101. The spacing distance may correspond to the height of the light shielding pattern BM and the second light shielding pattern BM2. For example, the light shielding pattern BM may have a height of 8 μm, and the second light shielding pattern BM2 may have a height of 8 μm. Thus, the air gap AG2 may have a height of 16 μm.

Further, the inner end BMie of the light shielding pattern BM is not in contact with the adhesive layer 102. Further, the inner end BM2ie of the second light shielding pattern BM2 is not in contact with the adhesive layer 102. Accordingly, the light shielding pattern BM and the second light shielding pattern BM2 may be prevented from generation of bubbles or chafing.

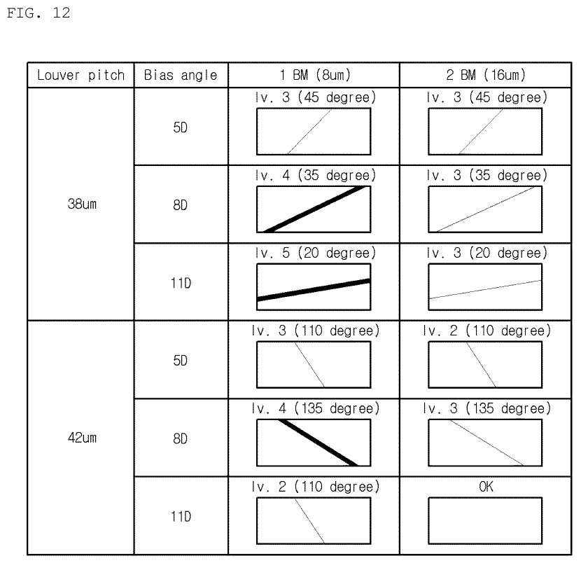

Meanwhile, the air gap AG2 according to the embodiment shown in FIG. 11 is thicker than the air gap AG according to the embodiment shown in FIG. 6, thereby further improving the moiré phenomenon. Below, descriptions will be made with reference to FIG. 12.

FIG. 12 is a view showing that the moiré phenomenon is decreased according to another embodiment of the disclosure.

Referring to FIG. 12, the levels of moiré are shown according to an embodiment of the disclosure when the light shielding pattern is a single layer (1 BM) and when the light shielding pattern is a double layer (2 BM).

In the case of a viewing angle control layer manufactured with a louver pitch of 38 μm, when a bias angle is set to 5 degrees (5D), 3-level moiré was observed in a direction of 45 degrees with the 1 BM, but 2-level moiré was observed with the 2 BM. When a bias angle is set to 8 degrees (8D), 4-level moiré was observed in a direction of 35 degrees with the 1 BM, but 3-level moiré was observed with the 2 BM. When a bias angle is set to 11 degrees (11D), 5-level moiré was observed in a direction of 20 degrees with the 1 BM, but 3-level moiré was observed with the 2 BM.

In the case of a viewing angle control layer manufactured with a louver pitch of 42 μm, when a bias angle is set to 5 degrees (5D), 3-level moiré was observed in a direction of 110 degrees with the 1 BM, but 2-level moiré was observed with the 2 BM. When a bias angle is set to 8 degrees (8D), 4-level moiré was observed in a direction of 135 degrees with the 1 BM, but 3-level moiré was observed with the 2 BM. When a bias angle is set to 11 degrees (11D), 2-level moiré was observed in a direction of 110 degrees with the 1 BM, but no moiré was observed with the 2 BM.

FIGS. 13 to 14 are cross-sectional views of a viewing angle control layer 350, in which FIG. 13 shows a viewing angle control function in a first mode, and FIG. 14 shows a viewing angle control function in a second mode.

The viewing angle control layer 350 may include a first substrate 10, a first electrode 20 on the first substrate 10, a light converter 30 on the first electrode 20, a second electrode 40 on the light converter 30, and a second substrate 50 on the second electrode 40. The light converter 30 may be disposed between the first electrode 20 and the second electrode 40.

The first substrate 10 may support the first electrode 20. The first substrate 10 may be rigid or flexible. Further, the first substrate 10 may be transparent. For example, the first substrate 10 may include a transparent substrate that can transmit light. The first substrate 10 may include a glass, plastic or flexible polymer film. Further, the first substrate 10 may be a curved or bended substrate.

The first electrode 20 may be disposed on one side of the first substrate 10. In more detail, the first electrode 20 may be disposed on the first substrate 10. In other words, the first electrode 20 may be disposed between the first substrate 10 and the second substrate 50. The first electrode 20 may include a transparent conductive material. For example, the first electrode 20 may include indium tin oxide, indium zinc oxide, copper oxide, tin oxide, zinc oxide, titanium oxide or the like metal oxide.

The second substrate 50 may be disposed on the first substrate 10. The second substrate 50 may be opposite to the first substrate 10. The second substrate 50 may include a material that can transmit light. The second substrate 50 may include a transparent material. The second substrate 50 may include the same or similar material to the first substrate 10 described above. Further, the second substrate 50 may be a flexible substrate. Further, the second substrate 50 may be a curved or bended substrate.

The second electrode 40 may be disposed on one side of the second substrate 50. In more detail, the second electrode 40 may be disposed beneath the second substrate 50. In other words, the second electrode 40 may be disposed on the side of the second substrate 50 facing the first substrate 10. In other words, the second electrode 40 may be disposed facing the first electrode 20 of the first substrate 10. In other words, the second electrode 40 may be disposed between the first electrode 20 and the second substrate 50. The second electrode 40 may include a transparent conductive material.

The light converter 30 may be disposed between the first substrate 10 and the second substrate 50. In more detail, the light converter 30 may be disposed between the first electrode 20 and the second electrode 40.

The light converter 30 may include a light transmitting portion 31, a highly refractive portion 32 around the light transmitting portion 31, and a transmittance variable portion 33 between the light transmitting portion 31 and the highly refractive portion 32. The transmittance variable portion 33 may be varied in light transmittance depending on voltage applied thereto. The light transmitting portion 31 may be disposed between the adjacent highly refractive portions 32. The highly refractive portion 32 may be disposed between the light transmitting portions 31.

For example, the highly refractive portion 32 may have a trapezoidal cross-section. In other words, the top side of the highly refractive portion 32 may be narrower than the bottom side thereof. However, without limitation, the cross-section of the highly refractive portion 32 may be shaped like an inverted trapezoid, a rectangle, a square, or other polygons. For example, the transmittance variable portion 33 may have an inverted trapezoidal cross-section. In other words, the top side of the transmittance variable portion 33 may be wider than the bottom side thereof.

The light transmitting portion 31 may include an opening OP. The opening OP may have the same cross-section as the transmittance variable portion 33. The cross-section of the opening OP may be shaped like, but not limited to, a trapezoid, a rectangle, a square, or other polygons.

The opening OP may be formed from the surface of the light transmitting portion 31.

One lateral side of the transmittance variable portion 33 may be in contact with the adjacent highly refractive portion 32, and the other lateral side may be in contact with the adjacent light transmitting portion 31. The bottom side of the transmittance variable portion 33 may be in contact with the light transmitting portion 31. The top side of the transmittance variable portion 33 may be in contact with the second electrode 40.

The light transmitting portion 31 can transmit light from the bottom to the top. The light transmitting portion 31 may include the transparent material. The light transmitting portion 31 may include a material capable of transmitting light.

The light transmitting portion 31 may include a photoalignment polymer material. Because the light transmitting portion 31 is formed by curing the photoalignment polymer material, the light transmitting portion 31 itself may be considered to include the photoalignment polymer material.

The light transmitting portion 31 may transmit light incident on one of the first substrate 10 and the second substrate 50 toward the other.

For example, as shown in FIGS. 13 and 14, the light transmitting portion 31 may transmit some light L1a of first light L1 provided from the bottom of the first substrate 10 toward the top. Below, a mode for a limited lateral viewing angle shown in FIG. 13 will be called a first mode, and a mode for a wide lateral viewing angle shown in FIG. 14 will be called a second mode.

The transmittance variable portion 33 may include a dispersion liquid 33a, and a light absorbing particle 33b. In more detail, the dispersion liquid 33a may be injected into the transmittance variable portion 33, and a plurality of light absorbing particles 33b may be dispersed in the dispersion liquid 33a.

The dispersion liquid 33a may include a material that disperses the light absorbing particles 33b. The dispersion liquid 33a may include a transparent material.

The light absorbing particles 33b may be dispersed in the dispersion liquid 33a. In more detail, the plurality of light absorbing particles 33b may be disposed being spaced apart from one another in the dispersion liquid 33a. The light absorbing particle 33b may include a material capable of absorbing light. The light absorbing particles may have a color.

The transmittance variable portion 33 may have light transmittance varied depending on the light absorbing particles 33b. In more detail, the transmittance variable portion 33 is varied in light transmittance depending on the light absorbing particles 33b, thereby serving as a light shielding portion and a light transmitting portion. In other words, the transmittance of light passing through the transmittance variable portion 33 may be varied depending on the dispersion and aggregation of the light absorbing particles 33b disposed in the dispersion liquid 33a.

For example, the viewing angle control layer 350 according to an embodiment may be switched over from the first mode to the second mode or from the second mode to the first mode by voltage applied to the first electrode 20 and the second electrode 40.

In more detail, in the first mode of the viewing angle control layer 350 according to an embodiment, the transmittance variable portion 33 serves as the light shielding portion, so that the transmittance variable portion 33 can block light at a certain angle. In other words, the viewing angle (or lateral viewing angle or left and right viewing angle) of a user who is looking from the outside may become narrower.

Further, in the second mode of the viewing angle control layer 350 according to an embodiment, the transmittance variable portion 33 serves as the light transmitting portion, so that both the light transmitting portion 31 and the transmittance variable portion 33 can transmit light. In other words, the viewing angle (or lateral viewing angle or left and right viewing angle) of a user looking from the outside may become wider.

Switching the transmittance variable portion 33 over from the first mode to the second mode, i.e., from the light shielding portion to the light transmitting portion may be implemented by moving the light absorbing particles 33b of the transmittance variable portion 33. In other words, the light absorbing particles 33b have charges on their surfaces and move toward the first electrode or the second electrode according to the characteristics of the charges as voltage is applied thereto. Here, the light absorbing particles 33b may include electrophoretic particles.

The foregoing descriptions are merely the specific embodiments of the display apparatus.

Therefore, it is readily apparent to a person having ordinary knowledge in the art that various substitutions and modifications can be made without departing from the scope of the disclosure defined in the appended claims.

According to the disclosure, a display apparatus includes: a cover window; a light shielding pattern disposed on the cover window; a viewing angle control layer disposed on the light shielding pattern and spaced apart from the cover window; an adhesive layer disposed on the viewing angle control layer; and a display panel disposed on the adhesive layer.

An air gap may be formed between the cover window and the viewing angle control layer.

The viewing angle control layer may be in contact with an upper portion of an inner end of the light shielding pattern.

The adhesive layer may be in contact with an upper portion of an outer end of the light shielding pattern.
the adhesive layer may be in contact with a lateral portion of the viewing angle control layer.

The adhesive layer may not be in contact with the inner end of the light shielding pattern.

The display apparatus may further include a guide holder disposed on the display panel, and the guide holder may be in direct contact with an upper portion of the adhesive layer.

The display apparatus may further include a polarization film disposed between the adhesive layer and the display panel.

The display apparatus may further include a back plate and a heat dissipation plate disposed on the display panel.

The display apparatus may further include a second light shielding pattern disposed between the cover window and the light shielding pattern.

The cover window and the viewing angle control layer may be spaced from each other corresponding to the heights of the light shielding pattern and the second light shielding pattern.

The viewing angle control layer may be in direct contact with an upper portion of an inner end of the light shielding pattern.

It will be apparent to those skilled in the art that various modifications and variations can be made in the display apparatus of the present disclosure without departing from the technical idea or scope of the disclosure. Thus, it is intended that the present t disclosure cover the modifications and variations of this disclosure provided they come within the scope of the appended claims and their equivalents.

What is claimed is:

1. A display apparatus, comprising:
a cover window;
a light shielding pattern disposed on the cover window;
a viewing angle control layer disposed on the light shielding pattern and spaced apart from the cover window;
an adhesive layer disposed on the viewing angle control layer; and
a display panel disposed on the adhesive layer.

2. The display apparatus of claim 1, wherein an air gap is formed between the cover window and the viewing angle control layer.

3. The display apparatus of claim 1, wherein the viewing angle control layer is in contact with an upper portion of an inner end of the light shielding pattern.

4. The display apparatus of claim 1, wherein the adhesive layer is in contact with an upper portion of an outer end of the light shielding pattern.

5. The display apparatus of claim 4, wherein the adhesive layer is in contact with a lateral portion of the viewing angle control layer.

6. The display apparatus of claim 1, wherein the adhesive layer is not in contact with the inner end of the light shielding pattern.

7. The display apparatus of claim 1, further comprising a guide holder disposed on the display panel,
wherein the guide holder is in direct contact with an upper portion of the adhesive layer.

8. The display apparatus of claim 1, further comprising a polarization film disposed between the adhesive layer and the display panel.

9. The display apparatus of claim 1, further comprising a back plate and a heat dissipation plate disposed on the display panel.

10. The display apparatus of claim 1, further comprising a second light shielding pattern disposed between the cover window and the light shielding pattern.

11. The display apparatus of claim 10, wherein the cover window and the viewing angle control layer are spaced from each other corresponding to the heights of the light shielding pattern and the second light shielding pattern.

12. The display apparatus of claim 10, wherein the viewing angle control layer is in direct contact with an upper portion of an inner end of the light shielding pattern.
